(19) United States
(12) Patent Application Publication
(10) Pub. No.: US 2024/0356500 A1
(43) Pub. Date: Oct. 24, 2024

(54) AMPLIFIER WITH ACTIVE AUXILIARY NON-LINEARITY CANCELLATION CIRCUITRY

(71) Applicant: Apple Inc., Cupertino, CA (US)

(72) Inventors: Omar E. Elaasar, San Diego, CA (US); Ming-Da Tsai, Cupertino, CA (US)

(21) Appl. No.: 18/136,755

(22) Filed: Apr. 19, 2023

(51) Int. Cl. H03F 3/21; H03F 1/32; H03F 3/45; H04B 1/04

(52) U.S. Cl. CPC H03F 3/21; H03F 1/3211; H03F 3/45179; H04B 1/0475; H03F 2200/451

(57) ABSTRACT

This disclosure is directed to an amplifier with improved linearity compared to other amplifiers. The amplifier may include auxiliary active circuitry to reduce amplitude and/or phase non-linearity of a single-ended or differential common-source amplifier when generating amplified signals. As such, the amplifier may output the amplified signals having an output power across a range of output powers with improved linearity. For example, the amplifier may output the amplified signals with improved linearity when operating at a normal power mode and a power back-off mode. The auxiliary active circuitry may include common-gate amplifiers cross coupled with the common-source amplifiers.

### BACKGROUND

The present disclosure relates generally to wireless communication, and more specifically to amplifiers of radio frequency circuits facilitating the wireless communication.

In an electronic device, a transmitter and a receiver may each be coupled to one or more antennas to enable the electronic device to transmit and receive wireless signals. The transmitter and the receiver may each include various components including one or multiple amplifiers. The amplifiers may output amplified signals based on receiving input signals. For example, the amplifiers may amplify a signal received by the one or more antennas or amplify a signal for transmission by the one or more antennas. In some cases, one or more of the amplifiers may output the amplified signals with reduced linearity. For example, an amplifier may output the amplified signals with distorted amplitude gain and/or phase when operating in normal output power mode, reduced power mode (e.g., a power back-off mode), or both.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an amplifier circuit may include a bias resistor, a first common-source amplifier, and a second common-source amplifier coupled to the first common-source amplifier in parallel. The amplifier circuit may also include a first common-gate amplifier, a drain of the first common-gate amplifier being coupled to a drain of the second common-source amplifier, a source of the first common-gate amplifier being coupled to a gate of the first common-source amplifier and the bias resistor. Additionally, the amplifier circuit may include a second common-gate amplifier, a drain of the second common-gate amplifier being coupled to a drain of the first common-source amplifier, a source of the second common-gate amplifier being coupled to a gate of the second common-source amplifier and the bias resistor.

In another embodiment, an electronic device may include one or more antennas and an amplifier coupled to the one or more antennas. The amplifier may include a bias resistor receiving an input signal. Additionally, the amplifier may include a first common-source amplifier, a source of the first common-source amplifier being coupled to a ground connection, a drain of the first common-source amplifier to receive an input power and provide an amplified signal in response to the input signal. Further, the amplifier may include a first common-gate amplifier, a source of the first common-gate amplifier being coupled to a gate of the first common-source amplifier and the bias resistor, and a drain of the first common-gate amplifier being coupled to the drain of the first common-source amplifier.

In yet another embodiment, an electronic device may include one or more antennas and an amplifier coupled to the one or more antennas. The amplifier may include a bias resistor and a first common-source amplifier. The amplifier may also include a second common-source amplifier, a drain of the second common-source amplifier being coupled to a drain of the first common-source amplifier. Additionally, the amplifier may include a first common-gate amplifier, a drain of the first common-gate amplifier being coupled to the drain of the second common-source amplifier, and a source of the first common-gate amplifier being coupled to a gate of the first common-source amplifier and the bias resistor. Further, the amplifier may include a second common-gate amplifier, a drain of the second common-gate amplifier being coupled to the drain of the first common-source amplifier, and a source of the first common-gate amplifier being coupled to a gate of the second common-source amplifier and the bias resistor.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure; and

FIG. 5 is a schematic diagram of an amplifier circuit of FIGS. 3 and/or 4 with auxiliary active circuitry to generate an amplified signal with improved linearity across a range of output powers, according to embodiments of the present disclosure.

### DETAILED DESCRIPTION OF SPECIFIC EMBODIMENTS

When introducing elements of various embodiments of the present disclosure, the articles “a.” “an,” and “the” are intended to mean that there are one or more of the elements. The terms “comprising.” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to an amplifier with improved linearity compared to other amplifiers. The amplifier may include auxiliary active circuitry to reduce amplitude and/or phase non-linearity of the amplifier when generating amplified signals (e.g., output signals). As such, the amplifier may output the amplified signals having an output power across a range of output powers with improved linearity. For example, the amplifier may output the amplified signals with improved linearity when operating at a normal power mode and a power back-off mode. In some cases, the auxiliary active circuitry may also reduce an amplitude of harmonic signals and/or intermodulation distortion signals of the amplifier. The auxiliary active circuitry may generate destructive harmonic signals and/or intermodulation distortion signals that destructively combine with the harmonic signals and/or intermodulation distortion signals of the amplifier. In such cases, the auxiliary active circuitry may cancel or reduce the amplitude of the harmonic signals and/or the intermodulation distortion signals of the amplifier. Accordingly, the amplifier may include a large-signal voltage amplifier and/or a small-signal voltage amplifier with reduced distortions in the amplitude and/or phase of the amplified signals. Moreover, the amplifier may have reduced size and power consumption to output the amplified signals with the improved linearity compared to other amplifiers.

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. The power source 29 may provide input power to one or more components of the electronic device 10. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible. computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution® (LTE) cellular network. Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of electrical power, such as a rechargeable lithium polymer (Li-poly) battery and/or an alternating current (AC) power converter.

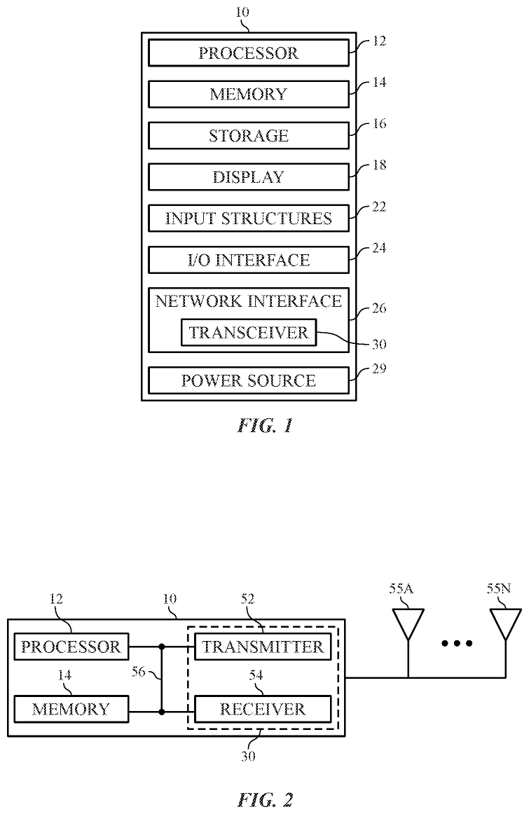

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

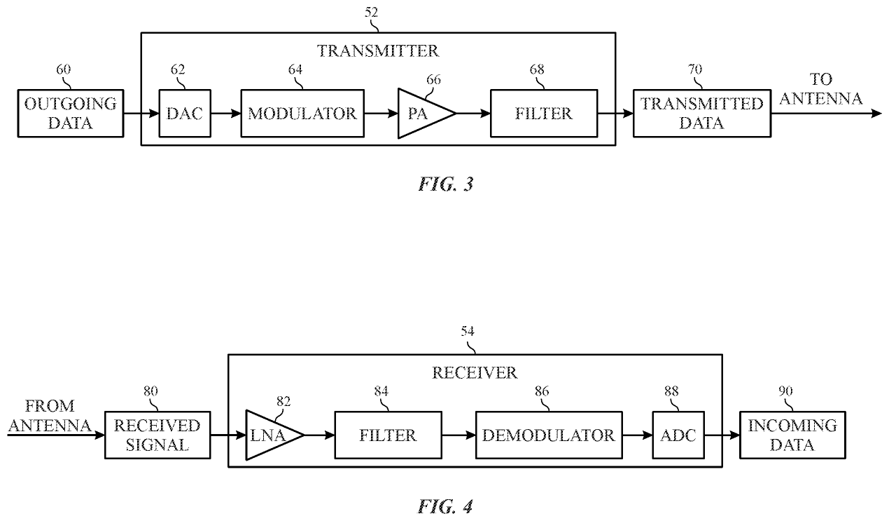

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the received signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

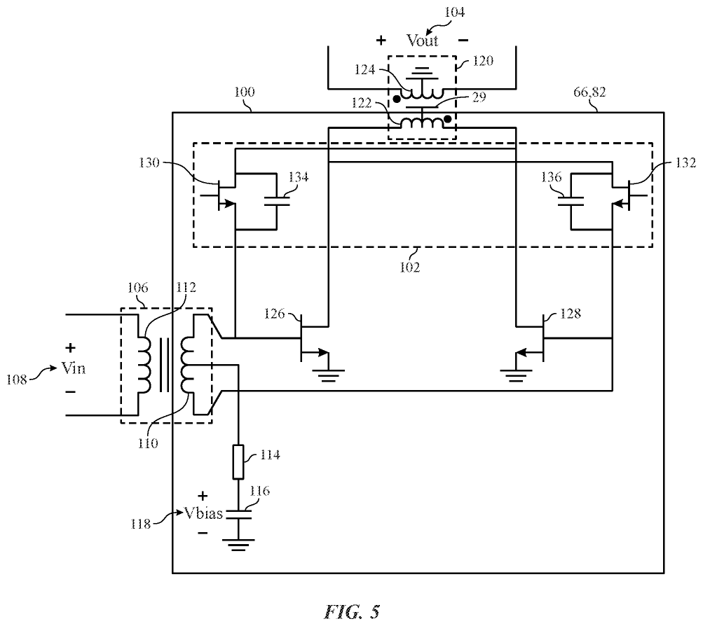

FIG. 5 is a schematic diagram of an amplifier circuit 100 with auxiliary active circuitry 102 (e.g., non-linearity cancellation circuitry). The amplifier circuit 100 may generate an amplified signal 104. The auxiliary active circuitry 102 of the amplifier circuit 100 may reduce non-linearity of a gain and/or a phase of the amplified signal 104 across a range of output powers. For example, the auxiliary active circuitry 102 may reduce the non-linearity of a gain and/or a phase of the amplified signal 104 based on operating at normal operation mode and power back-off mode. Similarly, the auxiliary active circuitry 102 may reduce non-linearity of the gain and/or the phase of the amplified signal 104 across a range of desired gains (e.g., −10 decibels (dB) to 0 dB, −3 dB to 3 dB, 0 to 10 dB, 3 to 20 dB, among other ranges).

In some embodiments, the electronic device 10 discussed above may include the amplifier circuit 100. For example, the PA 66 and/or the LNA 82 of the electronic device 10 may include the amplifier circuit 100. An input impedance matching network 106 of the amplifier circuit 100 may receive an input signal 108 such as the outgoing data 60 (e.g., analog converted and/or modulated signal 60) and/or the received signal 80. The input impedance matching network 106 may include a first input coil 110 (e.g., an input port) disposed on the amplifier circuit 100 and a second input coil 112 disposed on the circuit coupled to the amplifier circuit 100 (e.g., a source) providing the input signal 108 (e.g., the filter 68, the antenna 55, the filter 84, the demodulator 86, among other things).

In some cases, the input impedance matching network 106 may provide an input impedance (e.g., a high impedance) for receiving the input signal 108. In the depicted embodiment, the first input coil 110 may inductively couple to the second input coil to receive the input signal 108. It should be appreciated that in different embodiments, the first input coil 110 may couple to the second input coil in any other viable form (e.g., via transmission lines).

The first input coil 110 of the input impedance matching network 106 may be coupled to a bias resistor 114 (Rbias) and a bias capacitor 116. For example, the bias resistor 114 and the bias capacitor 116 may couple to a winding of (e.g., a middle of the winding of) the first input coil 110 such that the first input coil 110 is divided to a first side and a second side. In some cases, the bias resistor 114 and/or the bias capacitor 116 may receive and/or maintain a bias voltage 118 based on receiving the input signal 108. In the depicted embodiment, the bias voltage 118 is depicted across the bias capacitor 116. The bias resistor 114 may include a real impedance, a complex bias impedance, or both. For example, the bias resistor 114 may include a resistor in parallel with a capacitor and/or a resistor in series with an inductor, among suitable components, that result in a desired impedance.

An output impedance matching network 120 (e.g., an output port) of the amplifier circuit 100 may output an amplified signal 104 such as the amplified received signal 80 and/or the analog-converted amplified outgoing data 60 discussed above. The output impedance matching network 120 may include a first output coil 122 (e.g., the output port) disposed on the amplifier circuit 100 and a second output coil 124 disposed on the circuit coupled to the amplifier circuit 100 (e.g., a load) receiving the amplified signal 104 (e.g., the filter 68, the filter 84, the demodulator, 86, the antenna 55, among other things). In some cases, the output impedance matching network 120 may provide an output impedance (e.g., a high impedance) for providing the amplified signal 104.

In the depicted embodiment, the first output coil 122 may inductively couple to the second output coil 124. It should be appreciated that in different embodiments, the first output coil 122 may couple to the second output coil 124 in any other viable form (e.g., via transmission lines). Moreover, although in the depicted embodiment, the input signal 108 may be received and the amplified signal 104 (or the output signal) may be transmitted differentially, it should be appreciated that in different embodiments, the amplifier circuit 100 may receive and/or transmit the input signal 108 and/or the amplified signal 104 via single-ended connections.

The amplifier circuit 100 may include a first common-source amplifier 126 and a second common-source amplifier 128 to amplify the input signal 108 based on a desired output power. The first common-source amplifier 126 and the second common-source amplifier 128 may each include a switching device (e.g., a transistor) having a drain, a gate, and a source connection. The first common-source amplifier 126 and the second common-source amplifier 128 may form a common-source differential amplifier to amplify the input signal 108 based on a desired gain. As such, the first common-source amplifier 126 and the second common-source amplifier 128 may amplify the input signal 108 based on the desired gain to generate the amplified signal 104 having the desired output power.

The gate of the first common-source amplifier 126 is coupled to the first side of the first input coil 110. Moreover, the gate of the second common-source amplifier 128 is coupled to the second side of the first input coil 110. As such, the bias resistor 114 may be coupled in parallel to the gate of the first common-source amplifier 126 and the second common-source amplifier 128. Accordingly, the gates of the first common-source amplifier 126 and the second common-source amplifier 128 may sense a gate voltage based on the bias voltage 118 across the bias resistor 114 and/or the bias capacitor 116. The bias voltage 118 may drive the first common-source amplifier 126 and the second common-source amplifier 128. It should be appreciated that in different embodiments, the first side and the second side of the first input coil 110 may be similar or different. For example, in some cases, the first side and the second side of the first input coil 110 may provide different portions of the input signal 108. In alternative or additional cases, the first side and the second side of the first input coil 110 may provide equal (e.g., nearly equal) portions of the input signal 108.

The drains of the first common-source amplifier 126 and the second common-source amplifier 128 are coupled to the power source 29 discussed above. In the depicted embodiment, the power source 29 may be coupled to a winding of (e.g., a middle of the winding of) of the first output coil 122 such that the first output coil 122 is divided to a first side and a second side. As such, the drain of the first common-source amplifier may be coupled to the first side of the first output coil 122 and the drain of the second common-source amplifier may be coupled to the second side of the first output coil 122. In any case, the drains of the first common-source amplifier 126 and the second common-source amplifier 128 may receive electrical power. It should be appreciated that in different embodiments, the first side and the second side of the first output coil 122 may be similar or different. For example, in some cases, the first side and the second side of the first output coil 122 may provide different portions of the amplified signal 104. In alternative or additional cases, the first side and the second side of the first output coil 122 may provide different portions of the amplified signal 104. In specific cases, the position where the power source 29 is coupled to the winding of (e.g., a middle of the winding of) of the first output coil 122 may determine the distribution of the amplified signal between the first side and the second side of the first output coil 122 (e.g., the output port).

The sources of the first common-source amplifier 126 and the second common-source amplifier 128 are coupled to a ground connection. For example, each of the first common-source amplifier 126 and the second common-source amplifier 128 may be a class A biased or a class B biased common-source amplifier to generate the amplified signal 104 with the desired gain (e.g., a negative fundamental gain). As such, each of the first common-source amplifier 126 and the second common-source amplifier 128 may conduct electrical current from the power source 29 to the ground connection based on the respective gate voltages. For example, the first common-source amplifier 126 and the second common-source amplifier 128 may each conduct an amount of electrical current in response to receiving the respective gate voltages. Moreover, the amount the electrical current may correspond to the voltage amplitudes of the respective gate voltages.

With the foregoing in mind, the electrical current flow through the first common-source amplifier 126 and the second common-source amplifier 128 may correspond to an amplitude and a phase of the amplified signal 104. In particular, the amplitude and the phase of the amplified signal 104 may be determined based on an amount and a frequency (e.g., timing, delay) of the electrical current flow respectively. Moreover, as mentioned above, the gate voltages of the first common-source amplifier 126 and the second common-source amplifier 128 may correspond to the electrical current flow through the first common-source amplifier 126 and the second common-source amplifier 128. As such, the gate voltages of the first common-source amplifier 126 and the second common-source amplifier 128 may correspond to the amplitude and the phase of the amplified signal 104.

The gate voltages of the first common-source amplifier 126 and the second common-source amplifier 128 may be determined based on the bias voltage 118 and a current flow through the auxiliary active circuitry 102, as will be appreciated. The auxiliary active circuitry 102 may include a first common-gate amplifier 130 and a second common-gate amplifier 132. The first common-gate amplifier 130 and the second common-gate amplifier 132 may each include a respective switching device (e.g., a transistor) having a drain, a source, and a gate.

The drain of the first common-gate amplifier 130 may be coupled to the drain of the second common-source amplifier 128 and the second side of the first output coil 122. As such, the drain of the first common-gate amplifier 130 may sense whether electrical current is flowing from the power source 29 to the ground connection. The source of the first common-gate amplifier 130 may be coupled to the gate of the first common-source amplifier 126. A first capacitor 134 may be coupled to the drain and source of the first common-gate amplifier 130. The first capacitor 134 may be coupled in parallel to the first common-gate amplifier 130. The gate of the first common-gate amplifier 130 may be coupled to an alternative current (AC) short connection such as a direct current (DC) bias voltage (e.g., an AC short ground connection).

The drain and source of the first common-gate amplifier 130 may direct electrical current from the second side of the first output coil 122 (e.g., the power source 29) to the gate of the first common-source amplifier 126 in response to sensing a voltage difference. In particular, the first common-gate amplifier 130 may couple the second side of the first output coil 122 and the drain of the second common-source amplifier 128 to the gate of the first common-source amplifier 126 in response to sensing electrical current flow through the second common-source amplifier 128. As such, the drain of the first common-gate amplifier 130 may direct electrical current flow from the power source 29 (e.g., the input power) to the gate of the first common-source amplifier 126 in response to sensing the voltage difference. As discussed above, the second common-source amplifier 128 may conduct electrical current flow based on sensing the bias voltage 118 across the bias resistor 114 and/or the bias capacitor 116.

The drain of the second common-gate amplifier 132 may be coupled to the drain of the first common-source amplifier 126 and the first side of the first output coil 122. As such, the drain of the second common-gate amplifier 132 may also sense whether electrical current is flowing from the power source 29 to the ground connection. The source of the second common-gate amplifier 132 may be coupled to the gate of the second common-source amplifier 128. A second capacitor 136 may be coupled to the drain and source of the first common-gate amplifier 130. The first capacitor 134 may be coupled in parallel to the second common-gate amplifier 132. The gate of the second common-gate amplifier 132 may be coupled to the AC short connection (e.g., the DC bias voltage).

The drain and source of the second common-gate amplifier 132 may direct electrical current from the first side of the first output coil 122 (e.g., the power source 29) to the gate of the second common-source amplifier 128 in response to sensing a voltage difference. In particular, the second common-gate amplifier 132 may couple the first side of the first output coil 122 and the drain of the first common-source amplifier 126 to the gate of the second common-source amplifier 128 in response to sensing electrical current flow through the first common-source amplifier 126. As such, the drain of the second common-gate amplifier 132 may direct electrical current flow from the power source 29 to the gate of the second common-source amplifier 128 in response to sensing the voltage difference. Moreover, as discussed above, the first common-source amplifier 126 may conduct electrical current flow based on sensing the bias voltage 118 across the bias resistor 114 and/or the bias capacitor 116.

Moreover, as discussed above, the first common-source amplifier 126 and the second common-source amplifier 128 may ground electrical current in response to sensing the bias voltage 118. If not compensated for, in some cases, the first common-source amplifier 126 and the second common-source amplifier 128 may generate non-linear amplified signal 104 across a range of output powers (e.g., normal power mode, power back-off mode) and/or desired gains (e.g., −10 decibels (dB) to 0 dB, −3 dB to 3 dB, 0 to 10 dB, 3 to 20 dB, among other ranges). In particular, if not compensated for, in some cases, the amplified signal 104 may have amplitude non-linearity, phase non-linearity, and/or harmonic and intermodulation distortions across the range of output powers and/or desired gains. In the depicted embodiment, the amplifier circuit 100 may include the auxiliary active circuitry 102 to compensate for the amplitude non-linearity, phase non-linearity, and/or harmonic and intermodulation distortions across the desired range of output powers.

For example, the auxiliary active circuitry 102 may inject electrical current to the gates of the first common-source amplifier 126 and the second common-source amplifier 128 in response to receiving input signal 108. The injected electrical current may compensate for non-linear behavior of the amplifier circuit 100. In some cases, the injected electrical current may increase the current flow through the bias resistor 114 to increase the gate voltages. In such cases, the auxiliary active circuitry 102 may improve instantaneous gain compared to signal power characteristic (AM-AM) of the amplifier circuit 100. Moreover, the increased current flow through the common-gate amplifiers 130 and 132 may increase an input impedance of the amplifier circuit 100 resulting in compensation by the way of inducing capacitive feedback (e.g., positive capacitive feedback). As such, such capacitive feedback may generate negative real input impedance to favorably increase the input impedance (and/or input resistance) of the amplifier circuit 100. For example, the negative real input impedance may reduce an effect of (e.g., compensate for) existing positive impedance (and/or resistance).

In alternative or additional cases, the injected electrical current may reduce a value of parasitic capacitances of the amplifier circuit 100. In particular, the first common-source amplifier 126 and the second common-source amplifier 128 may form undesired gate-source parasitic capacitors during operation. The injected electrical current may cause the first common-gate amplifier 130 and the second common-gate amplifier 132 to form gate-source parasitic capacitors with opposite effect to cancel or reduce an effect of the undesired gate-source parasitic capacitors. For example, the first capacitor 134 may sense an undesired positive change (e.g., an undesired increase) in a gate-source parasitic capacitance of the first common-source amplifier 126 and a negative change (e.g., a decrease) in a gate-source parasitic capacitance of the first common-gate amplifier 130 destructively combining during operation. Moreover, the second capacitor 136 may sense an undesired positive change (e.g., an undesired increase) in a gate-source parasitic capacitance of the second common-source amplifier 128 and a negative change (e.g., a decrease) in a gate-source parasitic capacitance of the second common-gate amplifier 132 destructively combining during operation. As such, the auxiliary active circuitry 102 may reduce a phase distortion cause by undesired parasitic capacitances of the amplifier circuit 100 during operation.

Furthermore, the injected electrical current may increase a current flow through the bias resistor 114 increasing the input impedance of the amplifier circuit 100. Increasing the input impedance of the amplifier circuit 100 may also reduce phase distortions across a range of output powers (e.g., normal power mode, power back-off mode) and/or desired gains (e.g., −10 decibels (dB) to 0 dB, −3 dB to 3 dB, 0 to 10 dB, 3 to 20 dB, among other ranges). As such, the auxiliary active circuitry 102 may improve an instantaneous phase distortion compared to signal power characteristic (AM-PM) of the amplifier circuit 100.

In yet alternative or additional cases, the injected electrical current may reduce an amplitude of harmonic signals and/or intermodulation distortion signals of the amplifier circuit 100. The auxiliary active circuitry 102 may generate destructive harmonic signals and/or intermodulation distortion signals that destructively combine with the harmonic signals and/or intermodulation distortion signals of the amplifier circuit 100 during operation. In such cases, the auxiliary active circuitry 102 may cancel or reduce the amplitude of the harmonic signals and/or the intermodulation distortion signals of the amplifier circuit 100. Accordingly, the amplifier circuit 100 may be a large-signal voltage amplifier and/or a small-signal voltage amplifier with reduced distortions in the amplitude and/or phase of the amplified signals. Moreover, the amplifier may have reduced size and power consumption to output the amplified signals with the improved linearity compared to other amplifiers.

In alternative embodiments, a single-ended amplifier circuit 100 may include the first common-source amplifier 126, the first common-gate amplifier 130, and the bias resistor 114. For example, the input impedance matching network 106 and the output matching network may include circuitry to receive single-ended input signal 108 and provide single-ended amplified signal 104. In such embodiments, the drains of the first common-source amplifier 126 and the first common-gate amplifier 130 may be coupled together and to the output port. Similar to the embodiments discussed above, the single-ended amplifier circuit 100 may include bias resistor 114 coupled in parallel to the gate of the first common-source amplifier 126 such that injected electrical currents from the first common-gate amplifier 130 may improve linearity of the amplified signal 104.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform] ing [a function] . . . ” or “step for [perform] ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. An amplifier circuit comprising:
a bias resistor;
a first common-source amplifier;
a second common-source amplifier coupled to the first common-source amplifier in parallel;
a first common-gate amplifier, a drain of the first common-gate amplifier being coupled to a drain of the second common-source amplifier, a source of the first common-gate amplifier being coupled to a gate of the first common-source amplifier and the bias resistor; and
a second common-gate amplifier, a drain of the second common-gate amplifier being coupled to a drain of the first common-source amplifier, a source of the second common-gate amplifier being coupled to a gate of the second common-source amplifier and the bias resistor.

2. The amplifier circuit of claim 1, wherein the drains of the first common-source amplifier, the second common-source amplifier, the first common-gate amplifier, and the second common-gate amplifier are coupled to a power source.

3. The amplifier circuit of claim 2, wherein the drain of the first common-source amplifier and the drain of the second common-gate amplifier are coupled to a first side of an output port, the power source being coupled to the output port.

4. The amplifier circuit of claim 3, wherein the drain of the second common-source amplifier and the drain of the first common-gate amplifier are coupled to other side of the output port.

5. The amplifier circuit of claim 1, comprising a first capacitor coupled in parallel to the first common-gate amplifier and a second capacitor coupled in parallel to the second common-gate amplifier.

6. The amplifier circuit of claim 1, wherein the bias resistor is configured to electrically couple to a source to receive an input signal.

7. The amplifier circuit of claim 1, wherein the source of the first common-gate amplifier is coupled to the gate of the second common-source amplifier.

8. An electronic device comprising:
one or more antennas;
an amplifier coupled to the one or more antennas, the amplifier comprising
a bias resistor configured to receive an input signal,
a first common-source amplifier, a source of the first common-source amplifier being coupled to a ground connection, a drain of the first common-source amplifier configured to receive an input power and provide an amplified signal in response to the input signal, and
a first common-gate amplifier, a source of the first common-gate amplifier being coupled to a gate of the first common-source amplifier and the bias resistor, and a drain of the first common-gate amplifier being coupled to the drain of the first common-source amplifier.

9. The electronic device of claim 8, comprising a first capacitor coupled to the drain and the source of the first common-gate amplifier.

10. The electronic device of claim 8, comprising a second common-source amplifier, a drain of the second common-source amplifier being coupled to the drain of the first common-source amplifier.

11. The electronic device of claim 10, comprising a second common-gate amplifier, a drain of the second common-gate amplifier being coupled to the drain of the first common-source amplifier, a source of the first common-gate amplifier being coupled to a gate of the second common-source amplifier and the bias resistor.

12. The electronic device of claim 11, comprising a second capacitor coupled to a drain and a source of the second common-gate amplifier.

13. An electronic device comprising:
one or more antennas;
an amplifier coupled to the one or more antennas, the amplifier comprising
a bias resistor,
a first common-source amplifier,
a second common-source amplifier, a drain of the second common-source amplifier being coupled to a drain of the first common-source amplifier,
a first common-gate amplifier, a drain of the first common-gate amplifier being coupled to the drain of the second common-source amplifier, and a source of the first common-gate amplifier being coupled to a gate of the first common-source amplifier and the bias resistor, and
a second common-gate amplifier, a drain of the second common-gate amplifier being coupled to the drain of the first common-source amplifier, and a source of the second common-gate amplifier being coupled to a gate of the first common-source amplifier and the bias resistor.

14. The electronic device of claim 13, wherein the gate of the first common-source amplifier and the bias resistor are coupled to an input port and a source of the first common-source amplifier and a source of the second common-source amplifier are coupled to a ground connection.

15. The electronic device of claim 13, wherein the gate of the second common-source amplifier is coupled to an input port and a source of the second common-source amplifier is coupled to a ground connection.

16. The electronic device of claim 13, wherein the drain of the first common-source amplifier and the drain of the second common-source amplifier are coupled to a power source and an output port of the amplifier.

17. The electronic device of claim 16, wherein the output port is coupled to the one or more antennas.

18. The electronic device of claim 13, wherein a gate of the first common-gate amplifier is coupled to a gate of the second common-gate amplifier.

19. The electronic device of claim 18, wherein a first capacitor is coupled to the drain and the source of the first common-gate amplifier.

20. The electronic device of claim 18, wherein a second capacitor is coupled to the drain and the source of the second common-gate amplifier.
